(19) United States
(12) Patent Application Publication
(10) Pub. No.: US 2020/0350188 A1
(43) Pub. Date: Nov. 5, 2020

(54) INLINE VACUUM PROCESSING SYSTEM WITH SUBSTRATE AND CARRIER COOLING

(71) Applicant: INTEVAC, INC., Santa Clara, CA (US)

(72) Inventors: Terry Bluck, Santa Clara, CA (US); Arun Karamcheti, Saratoga, CA (US)

(21) Appl. No.: 15/929,378

(22) Filed: Apr. 29, 2020

Related U.S. Application Data
(60) Provisional application No. 62/842,376, filed on May 2, 2019.

(51) Int. Cl. H01L 21/67; H01L 21/677; H01L 21/203

(52) U.S. Cl. CPC H01L 21/67109; H01L 21/203; H01L 21/67727

(57) ABSTRACT

A substrate processing system, including a processing module having at least one sputtering source; a first buffer module positioned on a first side of the processing module; a second buffer module positioned on a second side of the processing module directly opposite the first side; a first cooling module attached to the first buffer module; a second cooling module attached to the second buffer module; a transport system transporting substrate carriers in a straight line through the first cooling module, the first buffer module, the processing module, the second buffer module and the second cooling module; wherein the system is arranged linearly in the order: first cooling module, the first buffer module, the processing module, the second buffer module and the second cooling module.

### RELATED APPLICATIONS

This application claims priority benefit from U.S. Provisional Application 62/842,376, filed on May 2, 2019, the entire disclosure of which is incorporated herein by reference.

### BACKGROUND

### 1. Field

This disclosure relates generally to the field of substrate processing, such as thin-film coating of substrates.

### 2. Related Art

Vacuum processing of substrates is well known in the art, and referred to sometimes as thin-film processing. When depositing thick films by PVD or performing other vacuum processes, such as ion etching, the substrate temperature can become a difficult problem to solve. In vacuum it is relatively easy to heat substrates, but difficult to cool them. This is especially the case for bi-facial substrates, when neither surface of the substrate may contact any part of the system, such as a chuck. However, allowing sufficient time for the substrates to cool or adding a chamber for cooling substrates will cause a significant drop in system productivity.

A need exists in the art for improved system architecture, which can be used for vacuum processing and provide for efficient cooling of the substrates. Moreover, there's a need in the art for machinery that can form the thin-film processing at commercially acceptable throughput and cost.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Disclosed embodiments provide a novel high productivity inline system which provides chambers for cooling substrates at high throughputs.

In the disclosed embodiments a carrier base vacuum processing system is provided. The system utilizes four carriers; two are in the system being alternately processed one at a time, while two are in atmosphere being unloaded and then reloaded with fresh substrates. A vacuum processing chamber is at the center of the system, and has two openings at opposing walls thereof. A buffer chamber is attached to each side of the processing chamber, such that carriers can be exchanged with the processing chamber via the opening. A cooling module is attached to each of the buffer chambers, wherein one of the cooling modules also serves as a load lock to transport carriers out of and into the vacuum environment.

In disclosed embodiments, four carriers are used: two in atmosphere and two in the vacuum environment. The two that are in atmosphere are being loaded with fresh substrates. The two that are in vacuum environment, one carrier is being cooled while one carrier is being processed. This allows for a high duty cycle for the processing chambers which allows the system to maintain high throughput.

The first loadlock chamber serves two purposes: one it is an atmosphere to vacuum load lock and it is also a vacuum isolated cooling chamber for the second of two carriers. The second chamber is an atmosphere to vacuum load lock for the first of two carriers and a reverse buffer for the first carrier. The second to last chamber is a reverse buffer for the second carrier. The last chamber is a vacuum isolated cooling chamber for the first carrier. The reverse buffer provides sufficient space for the carrier to clear the processing zone of the processing chamber, and then reverse its transport direction and reenter the processing zone.

A benefit of using isolated cooling chambers is that during cooling the pressure in the cooling chamber can be increased to enable better heat conduction. The pressure is advantageously increased by flowing into the isolated cooling chamber the same gas as used for the deposition process. In this manner process contamination upon opening the isolated chamber is avoided. In disclosed embodiments it is not necessary to elevate the pressure to atmospheric pressure, but rather it is sufficient to raise the pressure to sub-atmospheric pressure higher than the vacuum pressure level in the processing chamber. Prior to opening the isolation valve the cooling chamber may be pumped out and when the pressure inside the cooling chamber reaches near equilibrium with the processing chamber the isolation valve may be opened.

Disclosed aspects include a substrate processing system, comprising: a vacuum processing chamber having a first opening on a first wall and a second opening at a second wall opposite the first wall, and a valve gate on the first opening; a front buffer module having an attachment wall attached to the first wall of the processing chamber and having an opening on the attachment wall and a valve gate on an entrance wall opposite the attachment wall; a loadlock chamber having cooling plates therein, the loadlock chamber being attached to the entrance wall of the front buffer module, and having a valve gate positioned on exterior wall; a rear buffer module attached to the second wall of the processing chamber and having an opening matching the second opening on a first side thereof and a valve gate on a second side thereof, opposite the first side; a cooling module having cooling plates therein and attached to the second side of the rear buffer module; a linear track traversing the loadlock chamber, the front buffer chamber, the processing chamber, the rear buffer module and the cooling module; and two substrate carriers linearly traveling on the linear track such that at any given time only one of the carriers may be in one of the loadlock chamber, the front buffer chamber, the processing chamber, the rear buffer module and the cooling module, and the other carrier is at a different one of the loadlock chamber, the front buffer chamber, the processing chamber, the rear buffer module and the cooling module.

Disclosed aspects also include substrate processing system, comprising: a vacuum processing chamber having a first valve gate on a first wall and a second valve gate on a second wall opposite the first wall, the processing chamber having a processing zone commencing at the first wall and a buffer zone terminating at the second wall, the buffer zone being sufficiently large to enable a carrier to completely clear the processing zone such that when the carrier is in the buffer zone no processing is performed on a substrate mounted on the carrier; a front buffer module having an attachment wall attached to the first wall of the processing chamber and having an opening on the attachment wall and a valve gate on an entrance wall opposite the attachment wall; a loadlock chamber having cooling plates therein, the loadlock chamber being attached to the entrance wall of the front buffer module, and having a valve gate positioned on exterior wall; a cooling module having cooling plates therein and attached to the second wall of the processing chamber; a linear track traversing the loadlock chamber, the front buffer chamber, the processing chamber, the rear buffer zone and the cooling module; and two substrate carriers linearly traveling on the linear track such that at any given time one of the carriers may be in one of the loadlock chamber, the front buffer chamber, the processing chamber, the rear buffer module and the cooling module, and the other carrier is at a different one of the loadlock chamber, the front buffer chamber, the processing chamber, the rear buffer module and the cooling module.

Disclosed aspects further include a linear substrate processing system, comprising: a processing module having at least one sputtering source; a first buffer module positioned on a first side of the processing module; a second buffer module positioned on a second side of the processing module directly opposite the first side; a first cooling module attached to the first buffer module; a second cooling module attached to the second buffer module; a transport system transporting substrate carriers in a straight line through the first cooling module, the first buffer module, the processing module, the second buffer module and the second cooling module; wherein the system is arranged linearly in the order: first cooling module, the first buffer module, the processing module, the second buffer module and the second cooling module.

Yet further disclosed aspects include a method for processing substrates in a vacuum processing system, comprising: loading substrates onto a first and a second carriers for processing; loading the first and second carriers into the vacuum system and drawing vacuum within the system; isolating the first carrier inside a cooling chamber and at the same time transporting the second carrier in a linear fashion through a processing zone back and forth for a predetermined number of cycles, and thereafter isolating the second carrier inside a cooling chamber and at the same time transporting the first carrier in a linear fashion through a processing zone back and forth for a predetermined number of cycles. During the steps of isolating the first carrier inside a cooling chamber and isolating the second carrier inside a cooling chamber the method further includes raising the pressure inside the cooling chamber. Raising the pressure inside the cooling chamber may be done by flowing processing gas into the cooling chamber.

Other aspects and features of the invention would be apparent from the detailed description, which is made with reference to the following drawings. It should be appreciated that the detailed description and the drawings provides various non-limiting examples of various embodiments of the invention, which is defined by the appended claims.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a block schematic illustrating a top view of a system architecture according to an embodiment.

FIG. 2 illustrates an example of a substrate carrier, according to one embodiment.

FIG. 3 illustrate one embodiment of a processing chamber.

FIG. 4 illustrates an enlarged middle section of a processing system wherein processing chamber includes multiple processing modules, according to an embodiment.

FIG. 5 illustrates an example of a rear buffer forming part of the processing chamber, according to an embodiment.

FIG. 6 is a flow diagram illustrating a process according to an embodiment.

### DETAILED DESCRIPTION

Embodiments of the inventive system and method for fabricating thin-film coating and its wafer loading system will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments.

Disclosed embodiments may be implemented using one or more processing chambers. The system includes a linear transport track, such that carriers within the system cannot share the same space simultaneously, and may only move in a single linear direction back and forth. The system may be tailored such that when one carrier is processing a substrate, the other carrier is isolated in a cooling module to cool the substrate. The substrates may be made of semiconducting material, glass, etc., and may be processed on one or both surfaces. The processing may include etching material from the substrate, depositing material on the substrate, or both.

Benefits of the disclosed embodiments may be highlighted when the processing is performed in a pass-by mode, wherein the processing module is activated continuously while the substrate is passed in front of the processing module to thereby either remove or deposit material on the substrate. In such an arrangement, the carrier must have sufficient travel space so as to clear the substrate from the processing zone of the processing module. Otherwise the processing would not be uniform across the surface of the substrate. Hence, buffer chambers are included, wherein no processing is performed on the surface of the substrate.

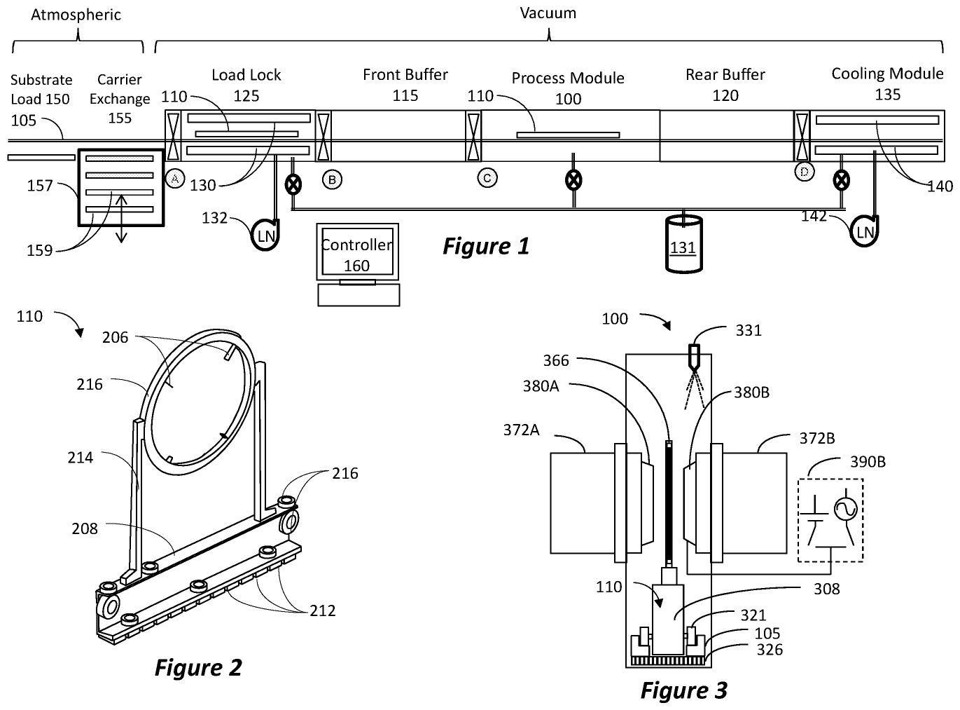

FIG. 1 is a block schematic illustrating a top view of a system architecture according to an embodiment. The system of FIG. 1 may be used to process substrates by e.g., sputtering deposition, ion etch, etc., wherein the substrate naturally gets heated by the processing on its surface. In this particular example, a single processing chamber 100 is used. A linear track 105, e.g., a monorail, traverses the entire system, such that substrate carriers 110 can ride on the track in and out of the system and from module to module inside the system. In the example shown, two carriers are inside the system, while two carriers are outside in atmospheric environment.

Processing chamber 100 has two transport windows, through which carriers can pass: one illustrated on the left side and one on the right side. The window on the left side has a valve gate, identified as gate c, which leads into the front buffer module 115, while the window on the right remain open at all times and leads into the rear buffer module 120. In this particular example, both buffer modules 115 and 120 are empty chambers, except for the linear track traversing through them.

The carriers enter and exit the vacuum environment of the system via loadlock chamber 125. Loadlock chamber 125 is fitted with cooling plates 130, which may include a chiller 132 circulating cooling fluid therein, e.g. liquid nitrogen. Similarly, cooling module 135 has cooling plates 140 therein, which may be connected to chiller 142. The cooling plates may be stationary or movable, and when cooling a substrate they are placed in close proximity to the substrate so as to remove heat from the substrate. In essence, the cooling plates operate as heat sinks, and the heat is removed by the chillers.

In the embodiment of FIG. 1 two additional stations are included in atmospheric environment: a substrate loading station 150 and a carrier exchange station 155, but any other arrangement for loading and unloading substrate may be used. In substrate loading station a processed substrate is removed from a carrier and a fresh substrate is loaded instead. In the carrier exchange station 155, carriers with processed substrates are removed from the loadlock 125 and carriers with fresh wafers are loaded onto the loadlock 125. The carrier exchange station 155 may include a platform 157 having linear track segments 159 thereupon. The platform 157 may be movable as illustrated by the double-headed arrow so as to line up any of the linear track segments 159 with the linear track 105, and then transporting a carrier from the segment 159 onto the linear track 105, or vice versa.

As illustrated in FIG. 1, in this particular example four valve gates A-D are provided to separate various modules within the vacuum environment of the system. The opening between the process module 100 and the rear buffer 120 need not have a valve gate. Also, the length of each of the front and rear buffer in the direction of the linear track is at least as long as the length of a substrate carrier in the direction of its travel.

The operation of the system is controlled by controller 160, which incorporates a program therein that, when executed causes the system to perform the operations as follows. Starting from a position wherein carrier exchange station 155 has two carriers loaded with fresh substrates and two carriers with processed substrates, platform 157 is moved to align a segment 159 having a carrier with fresh substrate with the linear track 105. Gate valve A is opened and the carrier, call it carrier i, is moved into loadlock 125. Gate valve B is opened and carrier i is moved into front buffer 115. The platform 157 is moved to align the second carrier with fresh substrate, call it carrier j, and carrier j is moved into loadlock 125. Gate valve A is closed and vacuum is drawn from loadlock 125 and front buffer 115. Meanwhile, carrier exchange station 155 and substrate loading station 150 are operated to remove the processed substrates from the two remaining carriers, call them k and l, loading fresh substrates, onto carriers k and l, and return carriers k and l onto the carrier exchange station 155.

Once vacuum level is achieved within loadlock 125 and front buffer 115, gate valve B is closed and gate valve C is opened. In this position, carrier j is isolated within loadlock 125, while carrier i has free passage among front buffer 115, process module 100 and rear buffer 120. Thus, carrier i may move back and forth on the linear track 105, each time passing through the processing chamber 100, thereby performing a pass-by processing, e.g., thin film deposition on the substrate loaded onto carrier i. The process is performed while flowing processing gas from gas supply 131 into the processing module 100. Once the programmed number of passes has been completed, gate valve D is opened and carrier i is moved into cooling module 135 (sometimes referred to as rear cooling module) and gate valve D is closed. Cooling plates 140 are activated to cool the substrate loaded onto carrier i. Also, optionally processing gas is flowed to the cooling module 135 to elevate the pressure within the cooling chamber, thereby enhancing heat conduction from the substrate to the cooling plates. The pressure maintained within the isolated cooling module may be sub-atmospheric, but higher than the pressure within processing module 100.

Gate valve B is now opened and carrier j is moved into front buffer 115 and then gate valve B is closed. Now, while carrier i is isolated within cooling module 135, carrier j has free passage among front buffer 115, process module 100 and rear buffer 120. Thus, carrier j may move back and forth on the linear track 105, each time passing through the processing chamber 100, thereby performing a pass-by processing, e.g., thin film deposition on the substrate loaded onto carrier j. Once the programmed number of passes has been completed, gate valve B is opened and carrier j is moved into loadlock 125 and gate valve B is closed. Cooling plate 130 now cool the substrate loaded onto carrier j. Also, optionally processing gas is flowed to the loadlock 125 to elevate the pressure within the cooling chamber, thereby enhancing heat conduction from the substrate to the cooling plates. The pressure maintained within the isolated loadlock 125 may be sub-atmospheric, but higher than the pressure within processing module 100.

Next, gate valve D is opened and carrier i is moved into rear buffer 120 and gate valve D is closed. In this position, there are two options. If further processing is required, then while carrier j is isolated within loadlock 125, carrier i may move back and forth on the linear track 105, each time passing through the processing chamber 100, thereby performing further pass-by processing, e.g., thin film deposition on the substrate loaded onto carrier i. Once the programmed number of passes has been completed, gate valve D is opened and carrier i is moved into cooling module 135 and gate valve D is closed. The processing of carrier j may now commence.

On the other hand, if no further processing was required, then carrier i is moved into front buffer 115 and gate valve C is closed. Gate valve B is opened and loadlock 125 and front buffer 115 are brought to atmospheric pressure. Gate valve A may then be opened and carriers i and j moved onto platform 157. The entire process may then repeat for carriers k and l.

Thus, during processing a first carrier is isolated in a first cooling chamber while a second carrier is moved linearly back and forth from a first buffer station, through a processing chamber and to a second buffer station, as many times as programmed. Once processing is completed the second carrier is moved into a second cooling chamber and the first carrier is moved linearly back and forth from the first buffer station, through the processing chamber and to the second buffer station, as many times as programmed. This entire process is repeated as many cycles as needed.

FIG. 2 illustrates an example of a substrate carrier, according to one embodiment. As illustrated in FIG. 2, the base 208 of carrier 110 has wheels 216, which engage the linear track 105 in the system (shown in other Figures). The base 208 also incorporates part of a magnetic transport system. Namely, in this embodiment, a magnetic transport mechanism is implemented as a lineal motor used to linearly transport the carrier between chambers and into and out of the system. The linear motor may be of a reluctance type. To interact with the linear motor, magnetic material, magnets, or both (212) are positioned on the base 208. In one embodiment, elements 212 are made of magnetic material. In other embodiment elements 212 are individual magnets. In yet other embodiment elements 212 are individual magnets attached to magnetic material. As described herein, the use of linear motor for the transport of carriers largely eliminates the need for enhanced friction to enable rapid acceleration and deceleration control.

Substrate support arms 214 are attached to the base 208, leading to frame 216. Frame 216 includes clips 206 which support the substrate at peripheral circumference thereof. This enables double sided processing without contacting either surface of the substrate. The support arms 214 and frame 216 are made as thin as possible, thereby enabling placing the cooling plates 130 and 140 very close to the substrate to efficiently remove heat from the substrate.

FIG. 3 illustrates a cross section of processing chambers 100, which is fitted with two sputtering sources 372A and 372B, according to one embodiment. Substrate 366 is shown mounted vertically onto carrier 110. Carrier 110 may have the same or similar construction to the carrier illustrated in FIG. 2. For example, base 308 has wheels 321, which ride on linear track 105. It is noted that the reverse can also be implemented, i.e., the carrier may have linear tracks which ride on wheels situated in a straight line in the chamber (not shown). The wheels 321 may be magnetic, in which case the linear track 105 may be made of paramagnetic material. In this embodiment the carrier is moved by linear motor 326, although other motive forces and/or arrangements may be used. Depositions source 372A is shown mounted onto one side of the chamber 100, while deposition source 372B is mounted on the other, opposite, side of the chamber 100. The carrier passes by deposition sources 372A and 372B, such that deposition is performed on both surfaces of the substrate as the substrate is moved passed the sources.

As shown in FIG. 3, sputter sources 372A and 372B generate ions for deposition onto the substrate 366. The ions are generated by sustaining plasma of process gas, e.g., argon gas provided from injector 331 or a showerhead, such that the argon ions in the plasma sputter targets made of the material to be deposited onto the substrate 366. A precursor gas may also be injected to react with the ions ejected from the target. When atoms of the material to be deposited are ejected from the target they are ionized by electrons accelerated within the plasma region. The ions are then directed towards the substrate. According to embodiments of the invention, the energy of the ions may be increased or reduced prior to impinging on the substrate by a field generated just ahead of the substrate. In the embodiment illustrated in FIG. 3, the field is generated by biasing shutters 380A and 380B, which are biased by an RF or DC power source, as exemplified by power source 390B.

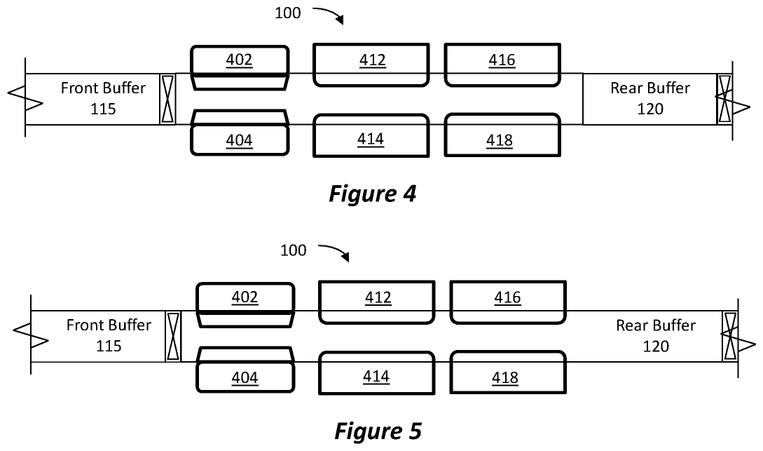

While the example illustrated in FIG. 3 shows two opposing sputtering sources, if only one side of the substrate is to be processed, then only one source is needed. Also, the chamber may have other processing modules, e.g., an etch module, and evaporation module, etc. Moreover, more than one processing modules may be mounted onto processing chamber 100. For example, FIG. 4 illustrates an enlarged middle section of a processing system wherein processing chamber 100 includes six processing modules, three on each side. For example, modules 402 and 404 may be etch modules that are activated only upon first pass to clean the substrate and perhaps remove a thin oxide layer formed on the substrate while it was in atmosphere. Modules 412-418 may be continuously energized deposition chambers which deposit the same or different materials on the substrate as it passes by.

The rear buffer 120 need not be a separate chamber, but may rather be part of the processing chamber 100. An example is illustrated in FIG. 5. Specifically, what is required is sufficient space for the carrier to travel such that the trailing edge of the substrate passes beyond the processing zone of processing modules 416 and 418. This is done to ensure uniformity of the deposited material over the substrate. Once the carrier moved a sufficient distance such that the substrate is completely outside the processing zone, then the carrier may reverse motion such that the trailing edge becomes the leading edge and enters the processing zone of modules 416 and 418. Thus, in this sense it may be said that processing chamber includes a processing zone and a buffer zone, wherein no processing is taking place in the buffer zone and the buffer zone is sufficiently long to enable the carrier to completely exit and clear the substrate from the processing zone.

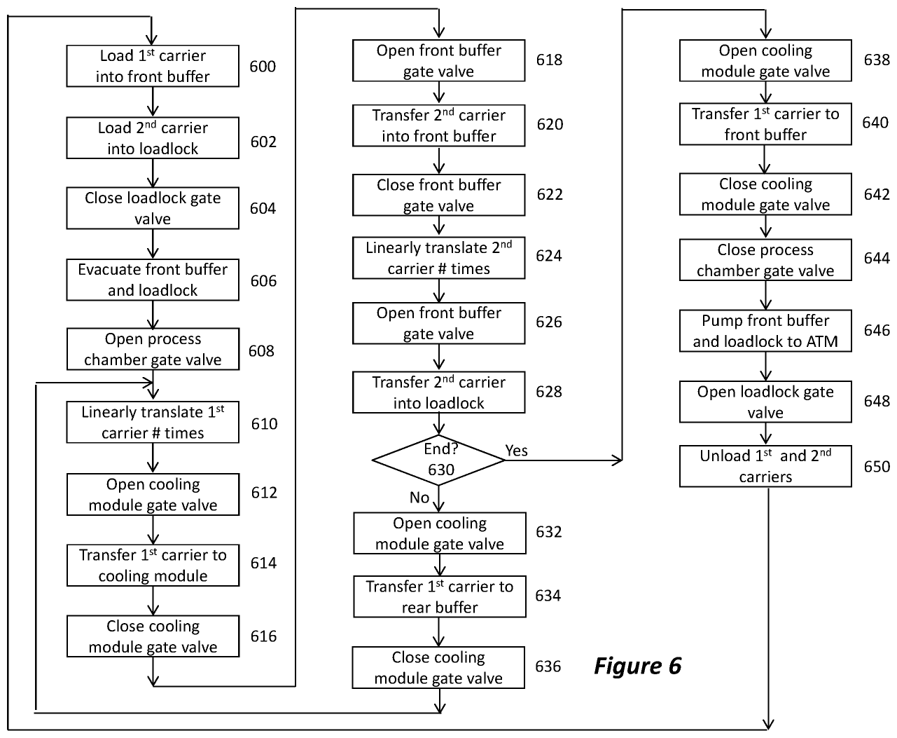

FIG. 6 is a flow diagram illustrating a process for processing substrates in a system having a processing chamber flanked by two buffer chambers on either side thereof, one cooling chamber attached to one of the buffer chambers, and another cooling chamber attached to the other buffer chamber, and having a linear track traversing the loadlock, buffer chambers, processing chamber and cooling chamber, according to an embodiment. In this example one of the cooling chamber and one of the buffer chambers also function as a loadlock. The process is continuously circular, such that in essence there is no real point of processing start or end, except for the initial point of initiating the system. Thus, the flow chart of FIG. 6 starts at the initiation point.

In step 600 the first carrier is loaded into the front buffer chamber and in 602 the second carrier is loaded into the loadlock (also the first cooling chamber). At 604 the gate valve of the loadlock is closed and at 606 the loadlock and the front buffer chambers are pumped to vacuum level. Notably, as can be appreciated from the entirety of the disclosure herein, each of the loadlock and front buffer performs two functions. The loadlock chamber also forms a front cooling chamber, while the front buffer also functions as a secondary loadlock chamber, as it also cycles between atmospheric and vacuum pressure levels.

Once vacuum level has been reached, at 608 the process chamber valve gate (gate C in FIG. 1) is opened. At this position of the system, one carrier is isolated inside a cooling chamber (in this case the second carrier is isolated inside loadlock chamber which is also a cooling chamber), and one carrier is being processed by being transported linearly back and forth between the front buffer, the processing chamber, and the rear buffer. In this example, the first carrier is being transported linearly from the front buffer, through the processing chamber, and to the rear buffer, and back, repeatedly as many number of times as programmed into the controller.

Once the number of cycles has been completed for the first carrier, at 612 the gate valve to the rear cooling module is opened, at 614 the first carrier is moved into the rear cooling module, and at 616 the gate valve to the rear cooling module is closed. Optionally, at this time gas is pumped into the rear cooling module. At 618 the gate valve of the front buffer is opened (valve B in FIG. 1), at 620 the second carrier is moved into the front buffer, and at 622 the gate valve of the front buffer is closed. Now the first carrier is isolated inside a cooling chamber and processing may commence on the second carrier. Thus, in essence in an embodiment of the method, the process proceeds by isolating one carrier inside a cooling chamber and linearly transporting a second carrier from a front buffer module, through a processing chamber, to a rear buffer module, back and forth repeatedly for a programmed number of times, and thereafter exchanging the carrier so that the processed carrier is isolated in a cooling chamber and the previously cooled carrier is linearly transported from a rear buffer module, through a processing chamber, to a front buffer module, back and forth repeatedly for a programmed number of times.

That is, in 624 the second carrier is cycled through the front buffer, processing chamber and rear buffer, back and forth, for a programmed number of times. At the end of this process of the second carrier, at 626 the gate valve for the front buffer is opened, and at 628 the second carrier is transferred into the loadlock. Optionally, at this time gas is pumped into the loadlock. At 630 it is determined whether processing on these two carriers is completed, or whether further processing is required. This can be simply by checking how many cycles each carrier has been processed. For example, for a deposition process the thickness of the deposited layer at each pass of the substrate is known, e.g., by measurement performed beforehand. The total required thickness is also known. So, from that one can derive the number of cycles each substrate must pass in front of the deposition module. However, when it is determined that after a certain number of passes the substrate's temperature rise is too high, the total number of required cycles can be divided into several periods of cycles, wherein after each period the carrier is transferred into a cooling module while the other carrier is processed.

When at 630 it is determined that further processing is required, if gas was pumped into the rear cooling module, the gas is pumped out to bring the pressure level of the rear cooling module to the same pressure as the processing module, or slightly above that level. At 632 the gate valve for the rear cooling module is opened, at 634 the first carrier is transferred into the rear buffer, and at 636 the gate valve of the rear cooling chamber is closed. The process now reverts to step 610 and repeats all the steps until it arrives at step 630 again.

When in step 630 it is determined that processing of both carriers has been completed, the process proceeds to step 638, wherein the gate valve of the rear cooling chamber is opened, at 640 the first carrier is transported to the front buffer and at 642 the gate valve of the rear cooling chamber is closed. At 644 the gate valve of the process chamber is closed. At 646 the front buffer and the loadlock are pumped back to atmospheric pressure. At 648 the gate valve of the loadlock is opened and at 650 the first and second carriers can be removed from the chamber and be reloaded with fresh substrate for processing. In the embodiment of FIG. 1, while the first and second carriers are being unloaded, two other carriers with fresh substrates are loaded into the loadlock and the process of FIG. 6 commences on the new carriers.

In disclosed embodiments, optionally when a carrier is isolated in a cooling chamber the pressure in the cooling chamber can be elevated to a sub-atmospheric pressure that will add a level of conductive cooling and greatly accelerate the cooling. The pressure should be determined to reach such level that it can be pumped back down to the process chambers operating vacuum before opening the isolation valve and processing the carrier. The gas used to increase the cooling rate may be the same gas or gases that the process module is using. The crossover point when the isolation slot valve opens would be when the pressure between cooling chamber and process chamber are at near equilibrium such that the opening of the isolation slot valve would not adversely affect the process.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

1. A substrate processing system, comprising:
a vacuum processing chamber having a first opening on a first wall and a second opening at a second wall opposite the first wall, and a valve gate on the first opening;
a front buffer module having an attachment wall attached to the first wall of the processing chamber and having an opening on the attachment wall and a valve gate on an entrance wall opposite the attachment wall;
a loadlock chamber having cooling plates therein, the loadlock chamber being attached to the entrance wall of the front buffer module, and having a valve gate positioned on exterior wall;
a rear buffer module attached to the second wall of the processing chamber and having an opening matching the second opening on a first side thereof and a valve gate on a second side thereof, opposite the first side;
a cooling module having cooling plates therein and attached to the second side of the rear buffer module;
a linear track traversing the loadlock chamber, the front buffer chamber, the processing chamber, the rear buffer module and the cooling module; and,
two substrate carriers linearly traveling on the linear track such that at any given time only one of the carriers may be in one of the loadlock chamber, the front buffer chamber, the processing chamber, the rear buffer module and the cooling module, and the other carrier is at a different one of the loadlock chamber, the front buffer chamber, the processing chamber, the rear buffer module and the cooling module.

2. The system of claim 1, further comprising a carrier exchange station positioned in atmospheric environment and attached to the loadlock chamber.

3. The system of claim 2, wherein the carrier exchange station comprises four linear track sections.

4. The system of claim 3, further comprising a substrate loading station attached to the carrier exchange station.

5. The system of claim 1, further comprising a controller having a program stored therein that when activated causes the controller to maintain one of the carriers isolated in the loadlock or the cooling module, while the other one of the carriers being transported back and forth through the front buffer module, the processing chamber and the rear buffer module a preprogrammed number of times.

6. The system of claim 1, wherein said vacuum processing chamber comprises a plurality of deposition modules situated to deposit material on a substrate transported inside the processing chamber.

7. The system of claim 6, wherein said vacuum processing chamber further comprises at least one etch module.

8. A substrate processing system, comprising:
a vacuum processing chamber having a first valve gate on a first wall and a second valve gate on a second wall opposite the first wall, the processing chamber having a processing zone commencing at the first wall and a buffer zone terminating at the second wall, the buffer zone being sufficiently large to enable a carrier to completely clear the processing zone such that when the carrier is in the buffer zone no processing is performed on a substrate mounted on the carrier;
a front buffer module having an attachment wall attached to the first wall of the processing chamber and having an opening on the attachment wall and a valve gate on an entrance wall opposite the attachment wall;
a loadlock chamber having cooling plates therein, the loadlock chamber being attached to the entrance wall of the front buffer module, and having a valve gate positioned on exterior wall;
a cooling module having cooling plates therein and attached to the second wall of the processing chamber;
a linear track traversing the loadlock chamber, the front buffer chamber, the processing chamber, the rear buffer zone and the cooling module; and,
two substrate carriers linearly traveling on the linear track such that at any given time one of the carriers may be in one of the loadlock chamber, the front buffer chamber, the processing chamber, the rear buffer module and the cooling module, and the other carrier is at a different one of the loadlock chamber, the front buffer chamber, the processing chamber, the rear buffer module and the cooling module.

9. The system of claim 8, wherein said vacuum processing chamber comprises a plurality of deposition modules situated to deposit material on a substrate position in the processing zone.

10. The system of claim 9, wherein said vacuum processing chamber further comprises at least one etch module.

11. A linear substrate processing system, comprising:
a processing module having at least one sputtering source;
a first buffer module positioned on a first side of the processing module;
a second buffer module positioned on a second side of the processing module directly opposite the first side;
a first cooling module attached to the first buffer module;
a second cooling module attached to the second buffer module;
a transport system transporting substrate carriers in a straight line through the first cooling module, the first buffer module, the processing module, the second buffer module and the second cooling module;
wherein the system is arranged linearly in the order: first cooling module, the first buffer module, the processing module, the second buffer module and the second cooling module.

12. The system of claim 11, further comprising a first gate valve between the first cooling module and the first buffer module, and a second gate valve between the second cooling module and the second buffer module.

13. The system of claim 11, wherein each of the first cooling module and the second cooling module comprises cooling plates.

14. The system of claim 11, wherein the processing module comprises a plurality of sputtering sources and at least one etch source.

15. The system of claim 11, wherein the transport system comprise a linear motor and a linear track extending through the first cooling module, the first buffer module, the processing module, the second buffer module and the second cooling module.

16. A method for processing substrates in a vacuum processing system, comprising:
loading substrates onto a first and a second carriers for processing;
loading the first and second carriers into the vacuum system and drawing vacuum within the system;
isolating the first carrier inside a cooling chamber and at the same time transporting the second carrier in a linear fashion through a processing zone back and forth for a predetermined number of cycles, and thereafter isolating the second carrier inside a cooling chamber and at the same time transporting the first carrier in a linear fashion through a processing zone back and forth for the predetermined number of cycles.

17. The method of claim 16, wherein the first carrier is isolated in a first cooling chamber and the second carrier is isolated in a second cooling chamber different from the first cooling chamber.

18. The method of claim 17, wherein at each passing through the processing zone the method comprises depositing a layer of material on the substrate.

19. The method of claim 16, wherein the predetermined number of cycles comprises a plurality number of cycles.

20. The method of claim 16, wherein transporting through a processing zone comprises linearly transporting a substrate through a buffer zone where no processing is performed on the substrate, through a sputtering zone wherein material is being deposited on the substrate, and through a second sputtering zone wherein no processing is performed on the substrate, and then reversing direction of travel of the substrate.

21. The method of claim 17, wherein when the first carrier is isolated in the first cooling chamber gas is pumped into the first cooling chamber and when the second carrier is isolated in the second cooling chamber gas is pumped into the second cooling chamber.
